(19) United States
(12) Patent Application Publication
(10) Pub. No.: US 2015/0069403 A1
(43) Pub. Date: Mar. 12, 2015

(54) FLEXIBLE SEMICONDUCTOR DEVICE, METHOD FOR MANUFACTURING THE SAME, AND DISPLAY DEVICE

(71) Applicant: Panasonic Corporation, Osaka (JP)

(72) Inventors: TAKESHI SUZUKI, Osaka (JP); YOSHIHIRO TOMITA, Osaka (JP); KOICHI HIRANO, Osaka (JP)

(21) Appl. No.: 14/455,446

(22) Filed: Aug. 8, 2014

(30) Foreign Application Priority Data
Sep. 9, 2013 (JP) 2013-186451

(51) Int. Cl. H01L 21/768; H01L 33/00; H01L 21/8234; H01L 23/485; H01L 27/15

(52) U.S. Cl. CPC H01L 21/768; H01L 23/485; H01L 27/15; H01L 21/8234; H01L 33/005; H01L 2933/0066
USPC 257/72; 438/26

(57) ABSTRACT

A flexible semiconductor device includes a wire embedded layer that has flexibility and has a first principal surface and a second principal surface, a thick wire embedded in the wire embedded layer so as to be substantially flush with the first principal surface of the wire embedded layer, and a thin film transistor element electrically connected to the thick wire. The thin film transistor element is disposed on the first principal surface of the wire embedded layer. The flexible semiconductor device is suitable for increasing the area and can be manufactured with a high productivity. A display device including the flexible semiconductor device and a method for manufacturing the flexible semiconductor device are also disclosed.

### BACKGROUND

1. Field

This disclosure relates to a flexible semiconductor device and a method for making the flexible semiconductor device. In particular, the disclosure relates to a flexible semiconductor device that includes a thin film transistor (TFT) element, a method for manufacturing the flexible semiconductor device, and a display device that includes the flexible semiconductor device.

2. Description of the Related Art

In recent years, various types of flat panel displays have been developed. Generally, a flat panel display includes a display medium constituted by elements that use liquid crystals, organic electroluminescence (EL), electrophoresis, or the like. A typical flat panel display, in particular, an active-type display, also includes a semiconductor device for driving images.

A display device that includes a semiconductor device is prepared by forming thin-film wires on an insulating substrate such as glass by a vacuum process (e.g., sputtering) and photolithography and then forming an image displaying unit such as a liquid crystal display (LCD) on the substrate with the thin-film wires.

While semiconductor devices of a flexible type (flexible semiconductor devices) have been developed as the semiconductor device used in such display devices, the productivity has been low because of the issues associated with production of the flexible semiconductor devices.

### SUMMARY

A flexible semiconductor device according to this disclosure includes a wire embedded layer that has flexibility and has a first principal surface and a second principal surface, a thick wire embedded in the wire embedded layer so as to be substantially flush with the first principal surface of the wire embedded layer, and a thin film transistor element electrically connected to the thick wire. The thin film transistor element is disposed on the first principal surface of the wire embedded layer.

In this disclosure, a flexible semiconductor device and a display device that can address various issues associated with the increase in size are realized. In particular, since a thick wire is used, the wiring has low electrical resistance and since the thick wire is embedded in a wire embedded layer, the adverse effects of protruding parts and recessed parts formed by the thick wire are effectively reduced. In sum, according to this disclosure, a flexible semiconductor device and a display device that are suitable for increasing the area can be obtained.

A manufacturing method thereof involves a relatively simple process of pressing a thick wire against a principal surface of a wire embedded element. Thus, a flexible semiconductor device suitable for increasing the area can be obtained with high productivity.

### BRIEF DESCRIPTION OF THE DRAWINGS

FIG. 1A is a schematic cross-sectional view of a flexible semiconductor device according to one embodiment of the disclosure, in which a thick wire and a wire embedded layer are completely flush with each other;

FIG. 1B is a schematic cross-sectional view of a flexible semiconductor device according to one embodiment of the disclosure, in which a thick wire slightly protrudes from a wire embedded layer;

FIG. 1C is a schematic cross-sectional view of a flexible semiconductor device according to one embodiment of the disclosure, in which a thick wire is slightly recessed from a wire embedded layer;

FIG. 2 is a schematic cross-sectional view of a flexible semiconductor device according to one embodiment of the disclosure, in which a wire embedded layer has a double layer structure;

FIGS. 3A to 3C are each a schematic cross-sectional view of a flexible semiconductor device according to one embodiment of the disclosure, in which a multilayered structure of a TFT element is illustrated;

FIG. 4 is a schematic cross-sectional view of a flexible semiconductor device according to an embodiment of the disclosure, in which an interlayer connection via is formed;

FIG. 5 is a schematic cross-sectional view of a flexible semiconductor device according to one embodiment of the disclosure in which a barrier layer is formed;

FIG. 6 is a circuit diagram of a drive circuit of a display device according to one embodiment of the disclosure;

FIG. 7A is a schematic plan view of a structure of a flexible semiconductor device mounted in a display device (structure close to an actual device);

FIG. 7B is a schematic cross sectional view of the structure illustrated in FIG. 7A;

FIG. 8A is a schematic plan view of a structure of a flexible semiconductor device mounted in a display device (structure close to an actual device);

FIG. 8B is a schematic cross sectional view of the structure illustrated in FIG. 8A;

FIG. 9 is a schematic cross-sectional view of a display device according to one embodiment of the disclosure;

FIG. 10 is a schematic cross-sectional view of a display device equipped with a color filter according to one embodiment of the disclosure;

FIGS. 11A to 11D are step cross-sectional views schematically illustrating a method for manufacturing a flexible semiconductor device according to this disclosure;

FIGS. 12A to 12D are step cross-sectional views schematically illustrating step (i) of the manufacturing method off this disclosure;

FIGS. 13A to 13F are step cross-sectional views schematically illustrating a method for manufacturing a flexible semiconductor device according to this disclosure in which an interlayer connection via is formed; and

FIGS. 14A to 14F are step cross-sectional views schematically illustrating a method for forming a flexible semiconductor device according to this disclosure in which a barrier layer is formed.

### DESCRIPTION OF THE PREFERRED EMBODIMENTS

Embodiments of this disclosure will now be described with reference to the drawings.

The issues are found to be as follows.

First, voltage reduction caused by wiring resistance becomes increasingly severe as the size (area) of flexible semiconductor devices increases. Although voltage reduction can be decreased by increasing the thickness of the wire, a long process time will be needed to form thick wires by a vacuum process, resulting in lower productivity.

Second, forming thick wires causes the substrate to have protruding parts and recessed parts. A thick planarizing layer needs to be formed in order to form a LCD on a substrate having protruding and recessed parts especially when the protruding and recessed parts are large. This decreases the productivity.

Third, to address issues related to the protruding and recessed parts on the substrate, a wire structure formed by filling grooves formed in a glass substrate with a metal has been suggested (for example, refer to Japanese Unexamined Patent Application Publication No. 2003-108029) but an expensive, lengthy process, such as reactive ion etching (RIE), is additionally needed to form grooves. Moreover, a vacuum thin film forming process needs to be performed for a long time in order to form wires. The proposal made in Japanese Unexamined Patent Application Publication No. 2003-108029 involves use of a glass substrate which is poor in flexibility and is significantly difficult to apply to a flexible semiconductor device.

A main object of this disclosure is to provide a flexible semiconductor device that can satisfactorily address the above-mentioned issues. To be more specific, a main object of the disclosure is to provide a flexible semiconductor device that can overcome various problems associated with the increasing size and to provide a method for manufacturing the flexible semiconductor device. In other words, a main object is to realize high productivity in flexible semiconductor devices suitable for increasing area.

In this disclosure, a whole new approach has been tried to achieve these objects and a flexible semiconductor device is disclosed as a result.

Embodiments of the disclosure will now be described.

For the sake of simplicity, structural elements having substantially the same function are represented by the same reference symbols in the drawings. The dimensional relationships (length, width, thickness, etc.) in each drawing do not reflect actual dimensional relationships.

Directions referred to in this specification are defined with reference to the positional relationship between a wire embedded layer 10 and a TFT element 30 of an EL device. For the sake of convenience, the vertical (up-down) direction in the drawing is used to describe directions in the drawing. To be specific, the side on which the TFT element 30 is positioned with respect to the wire embedded layer 10 is the “upper side” and the side opposite to the upper side is the “lower side”.

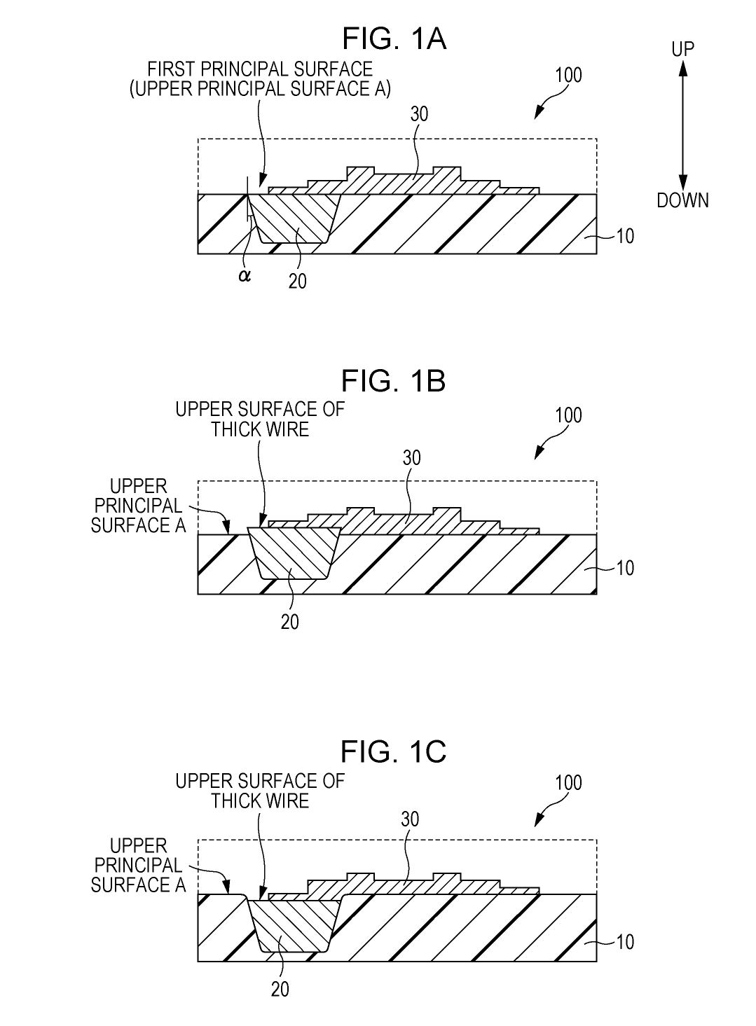

Embodiments of a flexible semiconductor device 100 according to the disclosure will now be described with reference to FIGS. 1A to 1C. FIGS. 1A to 1C are schematic cross-sectional views illustrating structures of the flexible semiconductor device 100 of this disclosure.

A flexible semiconductor device 100 according to this disclosure includes a wire embedded layer 10, a thick wire 20, and a TFT element 30. The wire embedded layer 10 is a flexible layer and has at least the thick wire 20 embedded therein. The thick wire 20 literally means a wire having a particularly large thickness as a wire. The thick wire 20 is embedded so as to be substantially flush with one of the principal surfaces of the wire embedded layer 10 (this one principal surface is hereinafter referred to as a first principal surface). In other words, as illustrated in the drawings, the first principal surface (upper principal surface A) of the wire embedded layer 10 and an upper surface of the thick wire 20 are substantially flush with each other when viewed as a whole. The TFT element 30 is disposed on the first principal surface (the upper principal surface A flush with the thick wire 20) of the wire embedded layer 10.

The flexible semiconductor device 100 according to this disclosure uses a wire with a large thickness, namely, a thick wire 20. Thus, the electrical resistance of the flexible semiconductor device 100 is effectively decreased. Since the thick wire 20 is appropriately embedded in the wire embedded layer 10, adverse effects of the recessed and protruding parts which would be generated by a thick wire are effectively reduced in the flexible semiconductor device 100 and good planarity is achieved as a whole. Accordingly, in this disclosure, a flexible semiconductor device that has low wiring resistance suitable for large-area screens is realized. A thick wire not only can contribute to decreasing the resistance but also can contribute to increasing mechanical strength. Thus, the flexible semiconductor device 100 exhibits high reliability against external force such as bending.

The wire embedded layer 10 is a layer having flexibility. As described below, since a film can be used to form the wire embedded layer 10, a light-weight flexible semiconductor device can be provided.

In the flexible semiconductor device 100 of this disclosure, the first principal surface (upper principal surface A) of the wire embedded layer 10 and the upper surface of the thick wire 20 are substantially flush with each other. This means that, when the flexible semiconductor device is viewed as a whole, the thick wire 20 is embedded in the wire embedded layer 10 so as to be in a state close to being flush with each other. In other words, “substantially flush” used in this disclosure refers to not only an embodiment illustrated in FIG. 1A in which the first principal surface (upper principal surface A) of the wire embedded layer 10 is completely flush with the upper surface of the thick wire 20 but also an embodiment illustrated in FIG. 1B in which the upper surface of the thick wire 20 is positioned to be slightly higher than the first principal surface (upper principal surface A) of the wire embedded layer 10 and an embodiment illustrated in FIG. 1C in which the upper surface of the thick wire 20 is positioned to be slightly lower than the first principal surface (upper principal surface A) of the wire embedded layer 10.

The differences among the embodiments illustrated in FIGS. 1A to 1C will now be described. In FIG. 1A, the upper principal surface A of the wire embedded layer 10 and the upper surface of the thick wire 20 are completely flush with each other. In other words, the upper principal surface A of the wire embedded layer 10 and the upper surface of the thick wire 20 lie on exactly the same plane. In such a case, the device as a whole exhibits high planarity, which is advantageous.

In FIG. 1B, the upper surface of the thick wire 20 is positioned to be slightly higher than the upper principal surface A of the wire embedded layer 10. In other words, the thick wire 20 is embedded in the wire embedded layer 10 in such a manner that the upper surface of the thick wire 20 protrudes from the first principal surface (upper principal surface A) of the wire embedded layer 10. According to this embodiment, the planarity is substantially achieved as a whole and due to the slightly protruding part, the electrical connection between the thick wire and the TFT element can be more securely established. Note that it is possible to achieve the state of complete flushness illustrated in FIG. 1A by using a barrier layer or the like described below.

In FIG. 1C, the upper surface of the thick wire 20 is positioned to be slightly lower than the upper principal surface A of the wire embedded layer 10. In other words, the thick wire 20 is embedded in the wire embedded layer 10 in such a manner that the upper surface of the thick wire 20 is recessed from the first principal surface (upper principal surface A) of the wire embedded layer 10. According to this embodiment, the planarity is substantially achieved as a whole and due to the slightly recessed part, the space needed for the electrical connection between the thick wire 20 and the TFT element is increased.

The embodiments illustrated in FIGS. 1B and 1C will now be described in detail. In FIG. 1B, the upper surface of the thick wire 20 slightly protrudes from the upper principal surface A of the wire embedded layer 10. In particular, the upper surface of the thick wire 20 is, for example, located 0 (exclusive) to about 1 μm higher than the upper principal surface A of the wire embedded layer 10. In another example, the upper surface of the thick wire 20 is located 0 (exclusive) to about 200 nm higher than the upper principal surface A of the wire embedded layer 10.

In FIG. 1C, the upper surface of the thick wire 20 is slightly recessed from the upper principal surface A of the wire embedded layer 10. In particular, for example, the upper surface of the thick wire 20 is located 0 (exclusive) to about 1 μm lower than the upper principal surface A of the wire embedded layer 10. In another example, the upper surface of the thick wire 20 is located 0 (exclusive) to about 200 nm lower than the upper principal surface A of the wire embedded layer 10.

As is understood from the foregoing description, the phrase “embedded to be substantially flush with” or similar phrases encompass those embodiments in which the surfaces are completely flush with each other and in which the difference in level between the surfaces is within ±1 μm in the vertical direction. In this disclosure, the embodiments in which the difference in level between the upper surface of the thick wire 20 and the upper principal surface A of the wire embedded layer 10 is within the range of ±1 μm are described as being “embedded to be substantially flush with” each other.

The thick wire 20 used in the flexible semiconductor device 100 of this disclosure is preferably composed of a metal having electrical conductivity and a relatively high melting point. Examples of such a metal include copper (Cu, melting point: 1083° C.), nickel (Ni, melting point: 1453° C.), aluminum (Al, melting point: 660° C.), and stainless steel (SUS). For example, the thick wire 20 may be formed of a metal foil. In other words, the thick wire 20 may be prepared by processing a metal foil. Copper foils and aluminum foils, which have low electrical resistance and are available at low cost, are preferable as the metal foil. The thickness of the thick wire 20 may be about 100 nm to 100 μm. For example, the thickness of the thick wire 20 is larger than the wires typically used in the related art. From this viewpoint, the thick wire 20 has a thickness of 500 nm to 100 μm in one example, a thickness of 1 μm to 70 μm in another example, and 2 μm to 5 μm in yet another example. Since the thick wire described in this disclosure generally has a large thickness, the cross-sectional area (area of a section taken in the thickness direction) is larger than that in the related art.

The width of the thick wire 20 may be about 5 μm to 1 mm. In the case where the thick wire 20 has a tapered shape as described below, the “width” refers to an average value of the minimum width and the maximum width. The thick wire 20 described herein is to have a large thickness and can achieve the desired low resistance despite a small width. In other words, according to this disclosure, the resistance can be decreased while decreasing the width of the thick wire 20. The width of the thick wire 20 may be, for example, 4 μm to 20 μm in one example, 4 μm to 18 μm in another example, and 4 μm to 10 μm in yet another example, although these are merely illustrative examples. According to such wires with finer widths, a relatively large space can be saved for other structural elements of the flexible semiconductor device, which is advantageous. Since the wire of this disclosure has a large thickness, undesirable voltage reduction can be avoided and the screen size can be effectively increased even if the width is the same as in the related art.

The thick wire 20 used in this disclosure is literally a “thick wire”. Thus, for example, the proportion of the wire embedded layer 10 occupied by the thick wire 20 is relatively large. In particular, regardless of whether the thick wire 20 protrudes or is recessed, the thick wire 20 occupies at least 50% of the wire embedded layer 10 in the thickness direction in one example, at least 60% of the wire embedded layer 10 in the thickness direction in another example, or at least 70% of the wire embedded layer 10 in the thickness direction in yet another example. The upper limit of this value is not particularly limited and may be, for example, 90%.

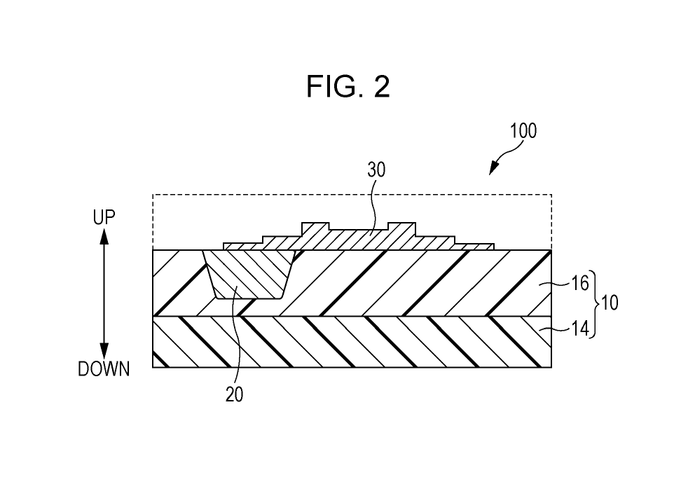

In the case where the wire embedded layer 10 has a double layer structure constituted by a flexible film 14 and an adhesive layer 16 as described below (refer to FIG. 2), the thick wire 20 occupies at least 50% of the adhesive layer 16 in the thickness direction, at least 60% of the adhesive layer 16 in the thickness direction in another example, or at least 70% of the of the adhesive layer 16 in the thickness direction in yet another example. The upper limit of this value is also not particularly limited and may be, for example, 90%.

The thick wire 20 is preferably tapered as illustrated in the drawings. The thick wire 20 preferably has a tapered shape at a cross section taken in the device thickness direction. To be more specific, the thick wire 20 described in this disclosure has a tapered shape in which the width gradually decreases from the first principal surface (upper principal surface A) of the wire embedded layer 10 toward the second principal surface of the wire embedded layer 10. According to this tapered shape, the thick wire 20 can be easily embedded in the wire embedded layer 10. Moreover, the degree or extent of embedding can be appropriately adjusted when the thick wire 20 has a tapered shape, which is advantageous. For example, the embodiment in which the upper surface of the thick wire 20 protrudes slightly from the upper principal surface A of the wire embedded layer 10 can be easily obtained by relatively shallowly embedding the thick wire 20 (refer to FIG. 1B). Alternatively, the embodiment in which the upper surface of the thick wire 20 is slightly recessed from the upper principal surface A of the wire embedded layer 10 can be easily obtained by more deeply embedding the thick wire 20 (refer to FIG. 1C). The taper angle α of the thick wire 20 illustrated in FIG. 1A is, for example, about 15° to about 70° and about 20° to about 45° in another example, although these values are merely examples.

The wire embedded layer 10 used in the flexible semiconductor device 100 may have a single layer structure or a multilayered structure, for example, a double layer structure. In the case where the wire embedded layer 10 has a double layer structure, the wire embedded layer 10 is preferably constituted by a flexible film 14 and an adhesive layer 16 on the flexible film 14, as illustrated in FIG. 2. The adhesive layer 16 fluidizes when pressure is applied during embedding of the thick wire 20 and thus exhibits an appropriately degree of a wire embedding function. The flexible film 14 has no fluidizability but has high thermal stability and mechanical strength. Accordingly, the flexible film 14 can serve as a core material. A wire embedded layer 10 having a double layer structure has an advantage of widening the range of the choice of the materials since respective layers can have respective functions.

The flexible film 14 of the wire embedded layer 10 may be, for example, an organic film or an organic/inorganic hybrid film. Examples of the material for the organic film include polyethylene terephthalate (PET), polyethylene naphthalate (PEN), polyimide (PI), and liquid crystal polymers. An example of the material for the organic/inorganic hybrid film is silsesquioxane. In other words, a resin sheet may be used as the flexible film 14. For example, an epoxy sheet, a PPE sheet, or the like may be used. From the viewpoint of incorporating a reinforcing material, a sheet obtained by impregnating a woven fabric or nonwoven fabric of glass fibers or aramid fibers with a resin may be used. The thickness of the flexible film 14 may be, for example, about 1 μm to about 500 μm.

The adhesive layer 16 of the wire embedded layer 10 may be a layer composed of an epoxy-system, polyimide-system, or PPE-system adhesive. The thickness of the adhesive layer 16 may be determined based on the thickness of the thick wire to be embedded. If the adhesive layer is excessively thin, the thick wire cannot be satisfactorily embedded. If the adhesive layer is excessively thick, the adhesive starts to flow and the thick wire cannot be embedded at a desired position. Accordingly, assuming that the thickness of the thick wire 20 is 0.1 μm to 10 μm, the thickness of the adhesive layer 16 is 1 μm to 30 for example.

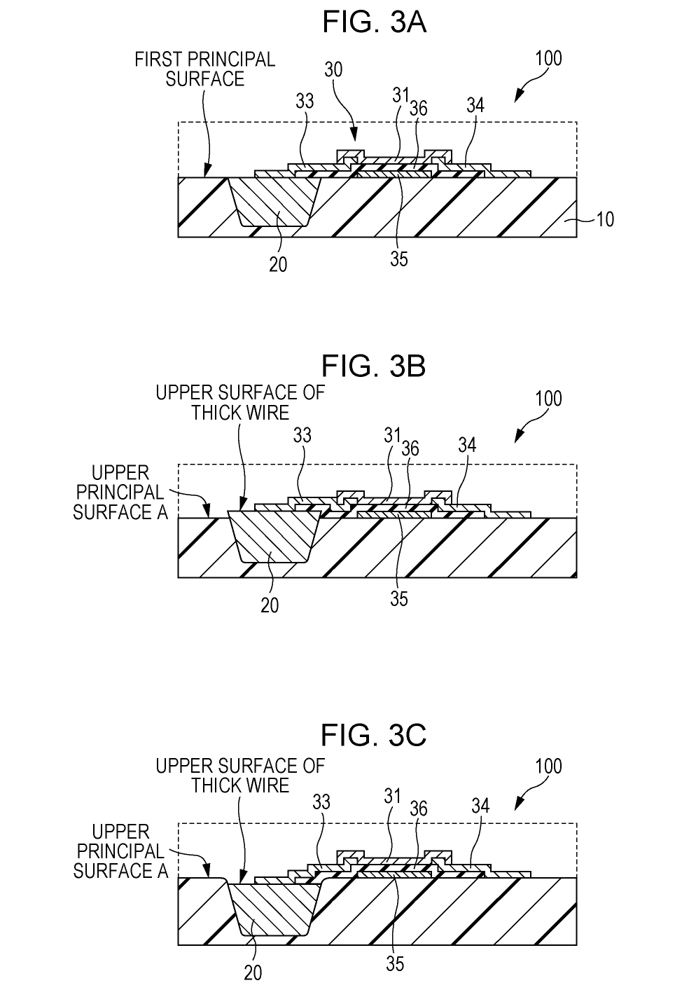

A TFT element 30 used in the flexible semiconductor device 100 is disposed on the first principal surface of the wire embedded layer 10, i.e., the upper principal surface A. As illustrated in FIGS. 3A to 3C, the TFT element 30 includes at least a semiconductor layer 31, a source electrode 33, a drain electrode 34, a gate electrode 35, and a gate insulating film 36. As illustrated in FIGS. 3A to 3C, the gate electrode 35 is formed on the upper principal surface A of the wire embedded layer 10, and the semiconductor layer 31 is formed on the gate insulating film 36 on the gate electrode 35, although this structure is a mere example. The source electrode 33 and the drain electrode 34 are electrically connected to the semiconductor layer 31. The structural elements (materials and thickness of the structural elements) of this TFT element are not particularly limited and may be the same as those used in typical TFT elements.

As illustrated in FIGS. 3A to 3C, the flexible semiconductor device 100 of this disclosure includes the thick wire 20 electrically connected to the source electrode 33 of the TFT element 30. In other words, due to the connection between the thick wire 20 and the source electrode 33, the thick wire 20 and the TFT element 30 are electrically connected to each other. The source electrode 33 is preferably positioned in at least part of the upper surface of the thick wire 20. In other words, the source electrode 33 is disposed so as to cover at least part of the upper surface of the thick wire 20 embedded in the wire embedded layer 10 by being substantially flush with the wire embedded layer 10. This corresponds to an embodiment in which an extraction electrode of the TFT element 30 is directly extracted from the upper surface of a thick wire. In such an embodiment, the extraction electrode is directly extracted from the upper surface of the thick wire. Thus, a flexible semiconductor device can be manufactured with a high productivity without additional manufacturing steps and without generating excess contact resistance caused by another extraction electrode or the like.

As illustrated in the drawings, the flexible semiconductor device 100 of this disclosure includes a TFT element 30 in an area outside the area above the thick wire 20, for example. In other words, for example, as illustrated in FIGS. 3A to 3C, the TFT element 30 on the upper principal surface A of the wire embedded layer 10 is disposed so as to be outside the area above the thick wire 20. In particular, while only the source electrode 33 is partly positioned in the area above the thick wire 20, other structural elements of the TFT element are not disposed above the thick wire 20. As is illustrated in this embodiment, “the TFT element is disposed in an area other than the area above the thick wire” means that the above-described structural elements (semiconductor layer, drain electrode, gate electrode, and gate insulating film) of the TFT element other than the source electrode are outside the area above the thick wire 20. In other words, these structural elements (semiconductor layer, drain electrode, gate electrode, and gate insulating film) and the thick wire 20 are positioned not to overwrap each other in the vertical direction in terms of positional relationship. In such an embodiment, the TFT element can be satisfactorily distanced from the border between the thick wiring and the wire embedded layer. In other words, even in the embodiment in which the thick wire 20 slightly protrudes from the wire embedded layer 10 (FIG. 3B) or in the embodiment in which the thick wire 20 is slightly recessed from the wire embedded layer 10 (FIG. 3C), adverse effects of the difference in level generated at the border between the thick wire 20 and the wire embedded layer 10 can be appropriately avoided and a planar TFT element can be provided. In particular, the semiconductor layer 31 of the TFT element can be appropriately made planar.

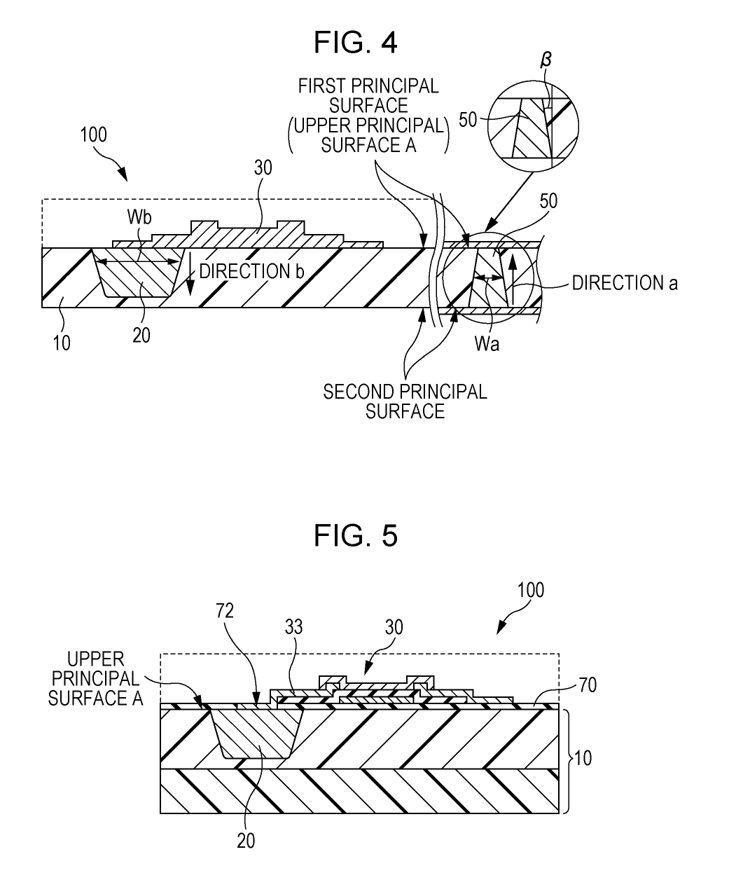

The flexible semiconductor device 100 of this disclosure may include an interlayer connection via. As illustrated in FIG. 4, an interlayer connection via 50 is disposed in the wire embedded layer 10 and extends along the thickness direction of the wire embedded layer 10. The interlayer connection via 50 may be connected to a wiring layer or the like disposed on the wire embedded layer 10, for example. The interlayer connection via 50 is preferably disposed so that an electrical signal from the wiring layer can be transmitted to a back surface or the like through a short distance and at a high wiring density. Moreover, when the interlayer connection via is composed of metal, the interlayer connection via can be used to release heat from the semiconductor layer since the heat resistance of the interlayer connection via is low. As a result, the life of the semiconductor layer can be extended and the reliability can be improved.

The interlayer connection via 50 preferably has a tapered shape. In other words, the interlayer connection via 50 has a tapered shape at a cross section taken in the device thickness direction. To be more specific, the interlayer connection via 50 according to this disclosure preferably has a tapered shape in which the width gradually increases from the first principal surface (upper principal surface A) of the wire embedded layer 10 toward the second principal surface of the wire embedded layer 10. When the interlayer connection via has a tapered shape, the area occupied by the via at the principal surface side A on which pixels are formed is small and thus high-density wiring is possible. In contrast, since the area of the via is large at the back surface, the alignment accuracy of the relative positions of via lands, other circuit elements, e.g., wiring, becomes less severe and the production process can be simplified. The taper angle β of the interlayer connection via 50 shown in FIG. 4 is, for example, about 15° to about 70° and about 20° to about 45° in another example.

In the flexible semiconductor device 100 of this disclosure, the interlayer connection via and the thick wire preferably have a reverse taper relationship. In other words, as illustrated in FIG. 4, the width Wa of the interlayer connection via 50 gradually decreases in the direction a, the width Wb of the thick wire 20 gradually decreases in the direction b, and the direction a and the direction b are opposite to each other. This means that the interlayer connection via of this disclosure has a reverse tapered, conical frustum shape in which the cross sectional area on the principal surface side A is smaller than that on the other side. According to the flexible semiconductor device 100 having this structure, the tapering effect of the thick wiring and the tapering effect of the interlayer connection via can both be exhibited.

The flexible semiconductor device 100 of this disclosure may further include a barrier layer. In particular, as illustrated in FIG. 5, a barrier layer 70 that directly covers the first principal surface (the upper principal surface A) of the wire embedded layer 10 can be provided. The barrier layer 70 preferably has an opening 72 in a local area above the thick wire 20 and the thick wire 20 and the source electrode 33 of the TFT element are connected to each other through the opening 72. The barrier layer here substantially means that a layer that blocks passage of moisture, water vapor, and the like. The barrier layer 70 extends the life of the semiconductor layer susceptible to moisture and water vapor and improves reliability. Because the opening 72 is formed and the connection between the thick wire 20 and the source electrode 33 is established through the opening 72, the barrier layer 70 also provides an effect of facilitating establishment of the electrical connection in addition to the barrier effect against moisture and water vapor. Note that since the source electrode 33 composed of metal or an oxide does not allow moisture or water vapor to pass, passage of moisture and water vapor through the opening in the barrier layer can be prevented. The barrier layer 70 may be an inorganic film of SiO₂, SiN, or the like or a multilayered film constituted by an inorganic film and a polymer film.

A display device according to this disclosure will now be described. A display device according to this disclosure includes the flexible semiconductor device described above.

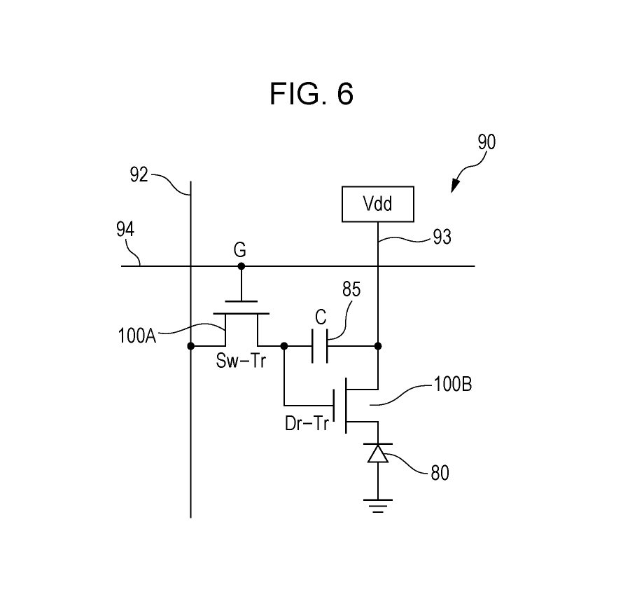

FIG. 6 is a circuit diagram used for describing a drive circuit 90 of a display device. The drive circuit 90 illustrated in FIG. 6 is to be mounted in a display device (for example, an organic EL display). In the drawing, a configuration of one pixel of the display device is illustrated. Each pixel of the display device of this example is constituted by a circuit in which two transistors (100A and 100B) and one capacitor 85 are combined. The drive circuit 90 includes a switching transistor (hereinafter may be referred to as “Sw-Tr”) 100A and a driving transistor (hereinafter may be referred to as “Dr-Tr”) 100B. Both transistors 100A and 100B can be constituted by the flexible semiconductor device 100 of this disclosure. It is possible to form a capacitor in a portion of the structure of the flexible semiconductor device 100. To be specific, the gate electrode of the Sw-Tr 100A is connected to a selection line 94. The source electrode and the drain electrode of the Sw-Tr 100A are respectively connected to a data line 92 and a gate electrode of the Dr-Tr 100B. The source electrode and the drain electrode of the Dr-Tr 100B are respectively connected to an electric power supply line 93 and a displaying unit (for example, an organic EL element) 80. A capacitor 85 is connected between the source electrode and the gate electrode of the Dr-Tr 100B.

In the pixel circuit having the above-described configuration, operation of the selection line 94 turns ON the Sw-Tr 100A and a drive voltage is input from the data line 92. The Sw-Tr 100A makes selection and a voltage is applied to the gate electrode of the Dr-Tr 100B as a result. A drain current corresponding to the voltage is supplied to the displaying unit 80 and the displaying unit (organic EL element) 80 emits light as a result. At the same time as a voltage is applied to the gate electrode of the Dr-Tr 100B, charges are accumulated in the capacitor 85. Due to these charges, the voltage application to the gate electrode of the Dr-Tr 100B continues for a certain period of time (capacity retention) after selection of the Sw-Tr 100A is canceled.

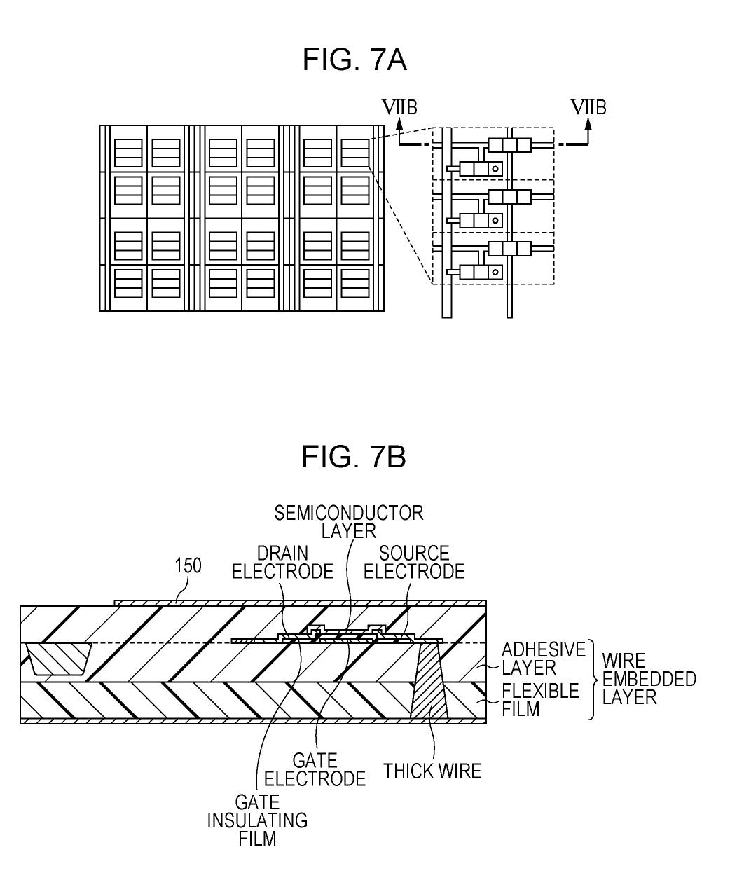

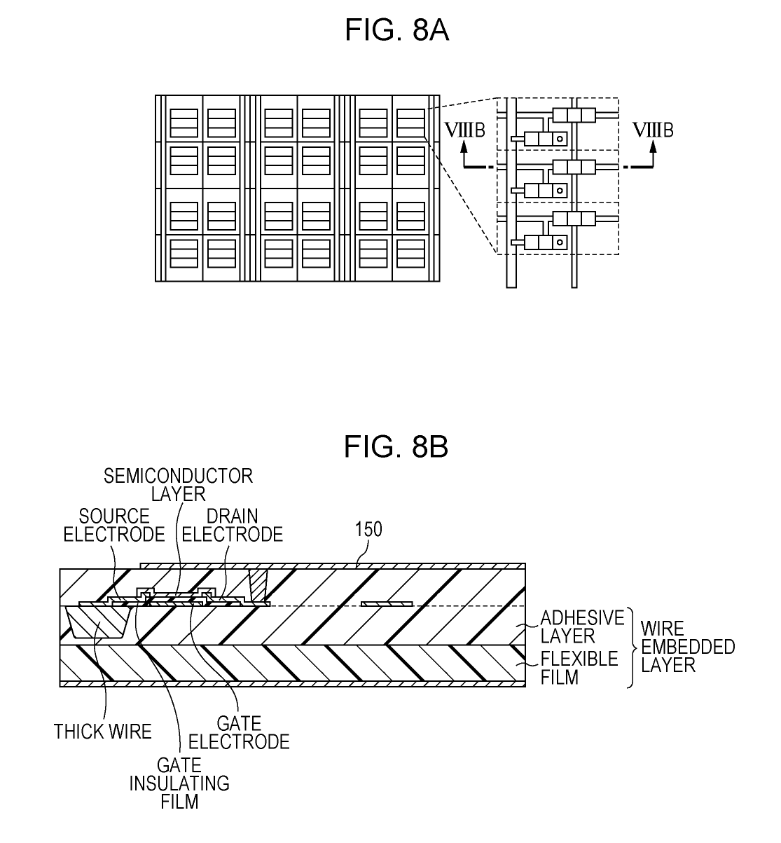

FIGS. 7A to 8B illustrate a structure of a flexible semiconductor device to be mounted in a display device. As illustrated in the drawings, in this flexible semiconductor device, a thick wire having a large thickness is embedded so as to be flush with a wire embedded layer and a TFT element is disposed on the wire embedded layer. The flexible semiconductor device mounted in the display device has a pixel electrode 150.

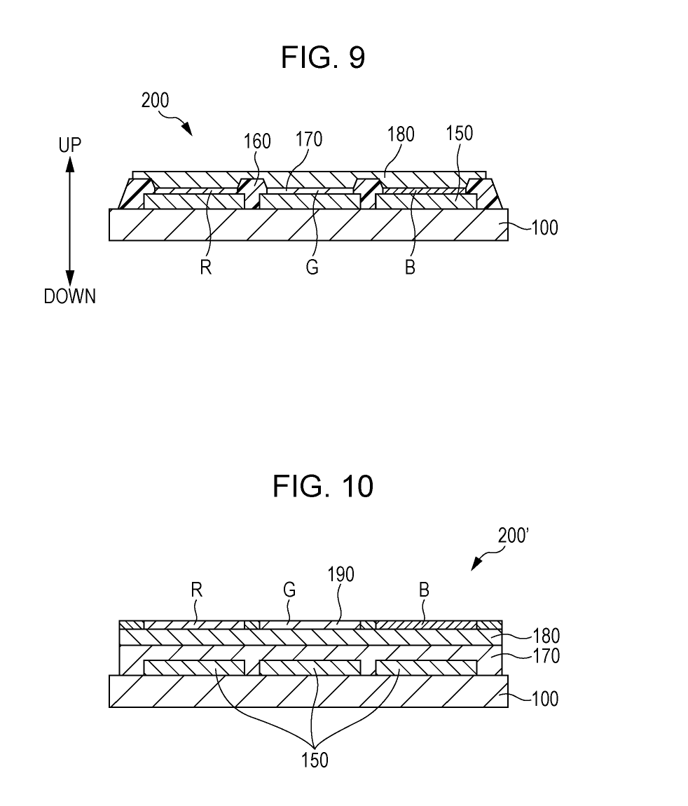

Next, an embodiment in which an image displaying unit is formed on a transistor or a circuit constituted by a transistor (in particular, an embodiment of an image displaying unit that includes plural pixels formed on a flexible semiconductor device) is described with reference to FIGS. 9 and 10.

Display devices according to embodiments illustrated in FIGS. 9 and 10 each include a flexible semiconductor device 100 and a display unit constituted by plural pixels formed on the flexible semiconductor device 100. The flexible semiconductor device 100 has the above-described structure and thus the thick wire is embedded in the wire embedded layer having flexibility so as to be substantially flush with the first principal surface of the wire embedded layer. In particular, the display device 200 (200′) illustrated in FIG. 9 (10) includes a display unit that includes a pixel electrode 150 disposed on the flexible semiconductor device 100, an emitting layer 170 disposed on the pixel electrode 150, and a transparent electrode layer 180 disposed on the emitting layer 170.

FIG. 9 is a cross-sectional view of an organic light-emitting diode (OLED) (organic EL) display device 200 in which three pixels of three colors, namely, red (R), green (G), and blue (B), are disposed on the flexible semiconductor device of this disclosure. An emitting layer 170 formed of a luminescent material of a corresponding color is disposed on the pixel electrode 150 of each of the R, G, and B pixels. A wall 160 is disposed between adjacent pixels so as to prevent mixing of the luminescent materials and facilitate aligning during placing of the EL materials. The transparent electrode layer (anode layer) 180 is formed on the upper surface of the emitting layer 170 so as to cover the entire pixels.

An example of the material for the pixel electrode 150 is a metal such as Cu as described above. In order to increase the light extraction efficiency by reflecting the light from a charge injection layer and an emitting layer and thereby improve the charge injection efficiency to the emitting layer 170, 0.1 μm of Al may be laminated on the surface of the pixel electrode 150 so as to form a multilayered structure (for example, Al/Cu) so that the pixel electrode 150 serves as a reflection electrode.

The material used for the emitting layer 170 is not particularly limited. Examples of the material include polyfluorene-system luminescent materials and substances having a dendrimer-like star-branched structure, such as dendrimer-system luminescent materials that use a heavy metal such as Ir or Pt at the center of a dendron skeleton of a dendrimer. The emitting layer 170 may have a single layer structure. Alternatively, the emitting layer 170 may have a multilayered structure, for example, an electron injection layer/emitting layer/hole injection layer structure that uses MoO₃ in the hole injection layer and LiF in the electron injection layer. ITO can be used in the transparent electrode serving as the anode.

The wall 160 between pixels may be composed of an insulating material. For example, a photosensitive resin that contains a polyimide as a main component or SiN can be used.

The display device may include a color filter as illustrated in FIG. 10. A display device 200′ illustrated in FIG. 10 includes a flexible semiconductor device 100, plural pixel electrodes 150 disposed on the flexible semiconductor device 100, an emitting layer 170 entirely covering the pixel electrodes 150, a transparent electrode layer 180 on the emitting layer 170, and a color filter 190 on the transparent electrode layer 180. In the display device 200′, the color filter 190 has a function of converting light from the emitting layer 170 into three light components, which are red, green, and blue, and thus the three pixels (R, G, and B pixels) can be configured. That is, according to the display device 200 illustrated in FIG. 9, the emitting layers separated from each other by walls respectively emit red, green, and blue light. In contrast, in the display device 200′ illustrated in FIG. 10, the light emitted from each emitting layer is of a single color (for example, white light) but as the light passes through the color filter 190, red light, green light, and blue light are generated.

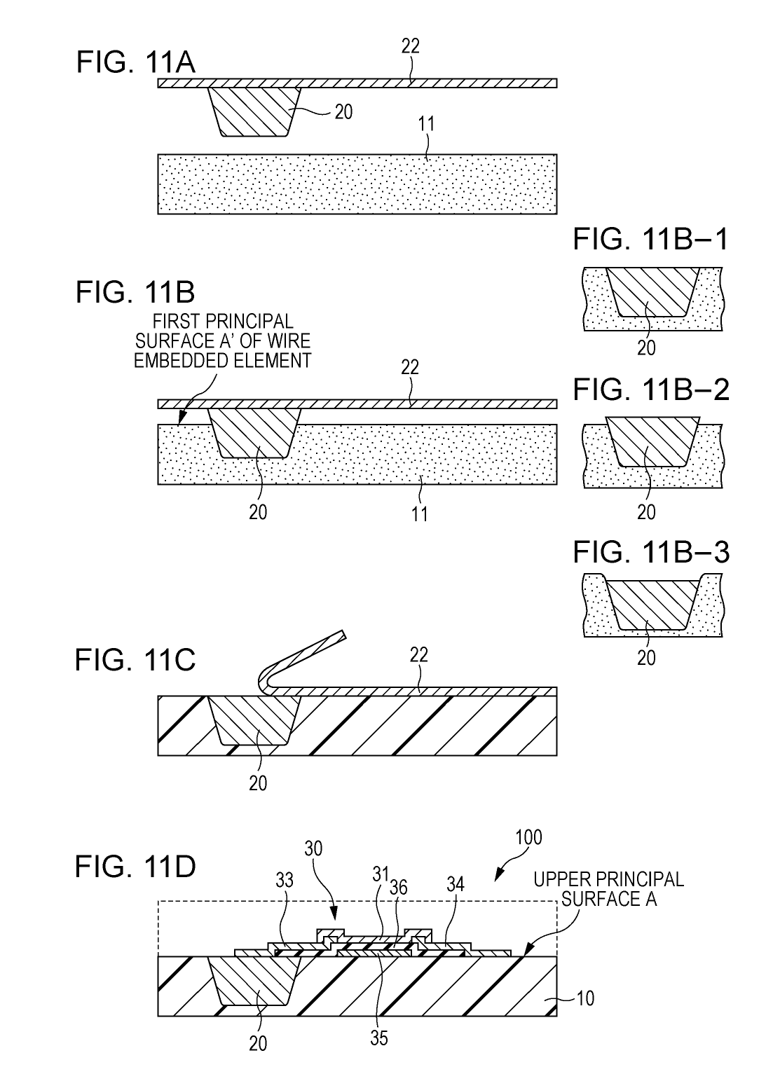

Next, referring to FIGS. 11A to 11D, a method for manufacturing a flexible semiconductor device 100 according to this disclosure is described. FIGS. 11A to 11D are step cross-sectional views used for describing a method for manufacturing a flexible semiconductor device 100.

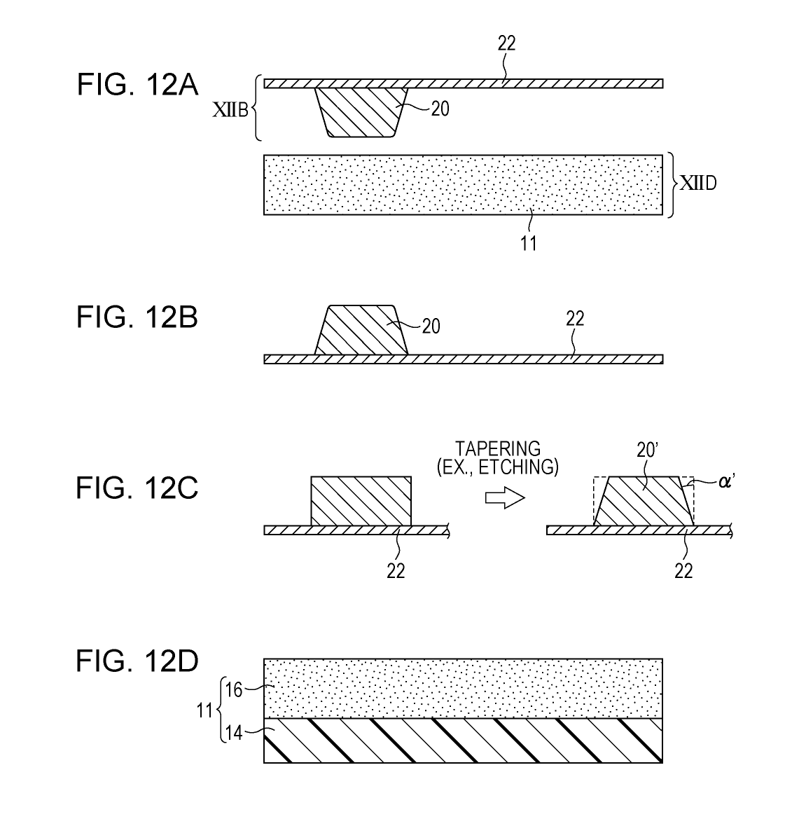

In implementing the manufacturing method of this disclosure, step (i) is first performed. That is, as illustrated in FIG. 11A and FIG. 12A, a thick wire 20 and a wire embedded element 11 having flexibility are prepared first.

The thick wire 20 can be obtained by processing a metal foil. In this manner, a thick wire having a large thickness, a large cross-sectional area, and low resistance can be obtained with a high productivity compared to when a vacuum process is employed. The metal foil is preferably a copper foil or an aluminum foil since the electrical resistance is low as a wire and the cost is less. The thick wire 20 can be prepared as a single element or as a carrier-mounted thick wire in which the thick wire 20 is disposed on a carrier 22 (refer to FIG. 12A). The carrier-mounted thick wire is preferable since it is easy to handle during manufacturing is high. For example, a carrier-mounted copper film in which a copper foil for forming a wire is formed on a releasing layer on a carrier formed of PET or a copper foil may be used. The carrier 22 is not limited to a flexible substrate such as a plastic film, e.g., a PET film, or a metal foil, e.g., a copper foil, and may be a hard substrate such as a glass substrate. In any case, a thick wire material is formed on a carrier with a releasing layer therebetween if needed.

An example of a carrier-mounted copper foil is one that uses a PET film having a thickness of about 100 μm as the carrier 22 and is formed by laminating a copper foil having a thickness of 2 μm on an organic releasing layer on the carrier 22. The thickness of the copper foil may be determined on the basis of the wiring resistance needed. For example, from the viewpoints of decreasing the voltage reduction and reducing the signal delay, the wiring resistance is preferably as low as possible and thus the thickness is preferably large. However, embedding becomes difficult if the thickness is excessively large. Thus, the thickness of the copper foil in the carrier-mounted copper foil is within the range of 100 nm to 100 for example.

As discussed above, the thick wire 20 can be formed by processing a metal foil. For example, a thick wire is processed to have a tapered shape. That is, a metal foil is processed so that the width is gradually decreased. The taper angle α′ illustrated in FIG. 12C is, for example, about 15° to about 70° and about 20° to about 45° in another example. The thick wire of a tapered shape may be formed by etching a metal foil, for example (refer to FIG. 12C). In particular, the metal foil may be partially etched through photolithography so as to form a tapered thick wire 20.

The carrier-mounted thick wire can be obtained by performing photolithography and etching. A typical photolithography/etching process employed in circuit board production can be employed. For example, a desired wiring pattern (for example, a wiring pattern having a tapered cross section) can be obtained by bonding a dry film resist onto a copper foil (copper foil to be used in a carrier-mounted copper foil), laminating a photomask having a desired pattern on the dry film resist, performing exposure and development, and removing unnecessary parts of the copper foil with an iron chloride-hydrochloric acid-based etchant or a sulfuric acid-hydrogen peroxide-based etchant.

A wire embedded element 11 prepared in step (i) is a flexible member and will have a thick wire 20 embedded therein in the subsequent step (ii). For example, the wire embedded element 11 may be an uncured or semi-cured element and is preferably cured at the same time as or after the embedding of the thick wire 20 by applying heat and/or light.

The wire embedded element 11 may have a double layer structure. For example, as illustrated in FIG. 12D, the wire embedded element 11 may be constituted by a flexible film 14 and an adhesive layer 16 (for example, an adhesive layer in an uncured state or a semi-cured state) formed on the flexible film 14. Since the adhesive layer 16 fluidizes when pressure is applied at the time of embedding the thick wire in step (ii), the adhesive layer 16 can exhibit an appropriate wire embedding function. The flexible film 14 has no fluidizability but has high thermal stability and mechanical strength. Thus, the flexible film 14 can function as a core material. The specific examples of the material and thickness of the flexible film 14 and the adhesive layer 16 are the same as those listed in the description above relating to the flexible semiconductor device. For example, the wire embedded element 11 may be a flexible Kapton base material to which a protective film and an adhesive are applied.

After step (i), step (ii) is performed. As illustrated in FIG. 11B, the thick wire 20 is pressed against a first principal surface A′ of the wire embedded element 11 so as to have the thick wire 20 embedded in the wire embedded element 11 and make the principal surface A′ of the wire embedded element 11 to be flush with the thick wire 20.

For example, a carrier-mounted copper foil having a desired thick wire pattern shape is laminated on the wire embedded element 11 while having the thick wire pattern to directly oppose the wire embedded element 11, followed by applying heat and pressure by using a hot press, a roll laminator, or the like. As a result, the thick wire 20 can be embedded in the wire embedded element 11. During the process of embedding, the wire embedded element 11 in an uncured or semi-cured state, in particular, the adhesive layer of the wire embedded element 11, can be cured by heat.

The conditions for embedding are determined on the basis of the thickness of the thick wire, the curing temperature and the fluidizability of the wire embedded element, etc. For example, in the case where a thick wire prepared by patterning a Cu foil having a thickness of 5 μm and disposed on a carrier (a PET film having a thickness of 100 μm) is to be embedded in a substrate prepared by applying an epoxy-system adhesive in a semi-cured state serving as a wire embedded element to a polyimide film (Kapton EN) 10 μm in thickness so that the thickness of the applied adhesive was 10 μm, thermal pressing may be performed at a temperature of 160° C. and a pressure of 3 MPa for 30 minutes.

After embedding the thick wire, the carrier 22 is removed, as illustrated in FIG. 11C. The carrier is removed by fixing a part of the carrier and mechanically peeling off the carrier. Since the carrier-mounted copper foil includes a releasing layer, only the carrier can be removed while having the thick wire embedded in the wire embedded element.

In step (ii), the thick wire 20 may be embedded in the wire embedded layer 10 so that the upper principal surface A of the wire embedded layer 10 and the upper surface of the thick wire 20 are completely flush with each other (refer to FIG. 11B-1). Alternatively, the thick wire 20 may be embedded in the wire embedded layer 10 relatively shallowly or deeply. For example, as illustrated in FIG. 11B-2, the thick wire 20 may be embedded shallowly so that the upper surface of the thick wire 20 is positioned to be higher than the principal surface of the wire embedded element 11. In such a case, the thick wire is embedded in the wire embedded layer so that the upper surface of the thick wire protrudes from the first principal surface (upper principal surface A) of the wire embedded layer. In particular, the thick wire 20 may be embedded in the wire embedded element 11 shallowly so that the upper surface of the thick wire 20 is positioned to be 0 (exclusive) to about 1 μm higher than the upper principal surface of the wire embedded element 11 (or the wire embedded layer obtained therefrom), or, in another example, so that the upper surface of the thick wire 20 is positioned to be 0 (exclusive) to about 200 nm higher than the upper principal surface of the wire embedded element 11.

Alternatively, as illustrated in FIG. 11B-3, the thick wire 20 may be deeply embedded in the wire embedded element 11 so that the upper surface of the thick wire 20 is positioned to be lower than the principal surface of the wire embedded element 11. In such a case, the thick wire is embedded in the wire embedded element so that the upper surface of the thick wire is recessed from the first principal surface (upper principal surface A) of the wire embedded element. In particular, the thick wire 20 may be deeply embedded in the wire embedded element 11 so that the upper surface of the thick wire 20 is positioned to be 0 (exclusive) to about 1 μm lower than the upper principal surface of the wire embedded element 11 (or the wire embedded layer obtained therefrom) or 0 (exclusive) to about 200 nm lower than the upper principal surface of the wire embedded element 11 in another example.

In the case where a thick wire having a tapered shape in which the width gradually decreases is prepared as the thick wire in step (i), as illustrated in FIG. 11B, the surface of the thick wire 20, the surface having a relatively small width, is preferably pressed against the upper principal surface A′ of the wire embedded element 11 so as to have the thick wire 20 embedded in the wire embedded element 11 (or the wire embedded layer obtained therefrom). In this case, the thick wire 20 has a tapered shape in which the width gradually decreases from the first principal surface (upper principal surface A) of the wire embedded layer 10 in the resulting display device 100 toward the second principal surface. The thick wire 20 can be easily embedded in the wire embedded layer 10 by pressing the surface of the thick wire 20, the surface having a relatively small width, against the principal surface A′ of the wire embedded element 11. In particular, the extent of embedding can be appropriately adjusted. In other words, it becomes easier to have the thick wire 20 embedded relatively slightly shallowly so that the upper surface of the thick wire 20 slightly protrudes from the upper principal surface of the wire embedded element 11 (or the wire embedded layer obtained therefrom). Alternatively, it becomes easier to have the thick wire 20 embedded relatively slightly deeply so that the upper surface of the thick wire 20 is slightly recessed from the upper principal surface of the wire embedded element 11 (or the wire embedded layer obtained therefrom).

After step (ii), step (iii) is performed. As illustrated in FIG. 11D, a TFT element 30 is formed on the principal surface A of the wire embedded element. In particular, as illustrated in FIG. 11D, a TFT element 30 that includes at least a semiconductor layer 31, a source electrode 33, a drain electrode 34, a gate electrode 35, and a gate insulating film 36 is formed.

To be more specific, a gate electrode 35 is formed on the upper principal surface A of the wire embedded layer 10, and a semiconductor layer 31 is formed on a gate insulating film 36 on the gate electrode 35. The source electrode 33 and the drain electrode 34 are formed so as to electrically connect to the semiconductor layer 31. The TFT element 30 can be formed by the same method for forming a typical TFT element. Accordingly, the semiconductor layer, the source electrode, the drain electrode, the gate electrode, and the gate insulating film may be formed by typical methods.

For example, the source electrode 33 is formed to be positioned in at least a part of the upper surface of the thick wire 20 so as to connect to the thick wire 20. The TFT element 30 is, as illustrated in the drawing, preferably formed in an area outside the area above the thick wire 20. In other words, as illustrated in FIG. 11D, the TFT element 30 on the upper principal surface A of the wire embedded layer 10 is preferably formed at a position outside the area above the thick wire 20. To be more specific, the TFT element 30 is preferably formed such that only the source electrode 33 is positioned in the area above the thick wire 20 and other structural elements of the TFT element 30 are positioned outside the area above the thick wire 20.

A flexible semiconductor device 100 in which a thick wire having a large thickness is embedded in a flexible wire embedded layer so as to be substantially flush with the flexible wire embedded layer can be ultimately obtained through performing steps (i) to (iii) described above.

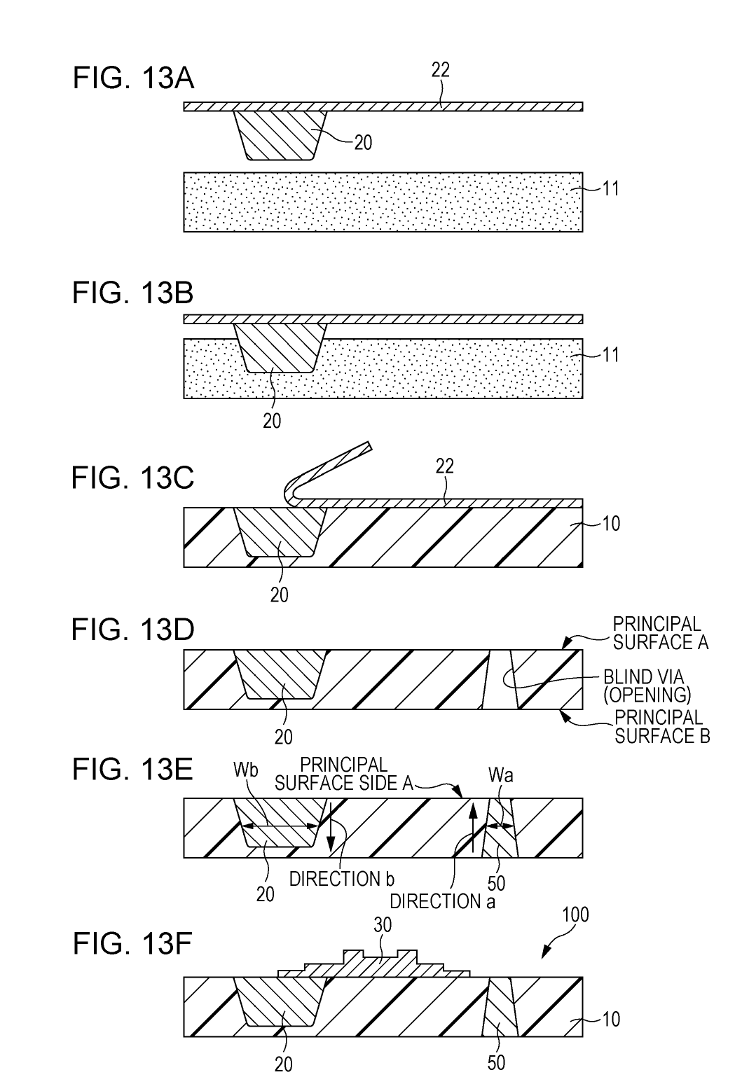

The manufacturing method of this disclosure may further include a step of forming an interlayer connection via. As illustrated in FIGS. 13A to 13F, the method may further include a step of forming an interlayer connection via 50 in a wire embedded layer (to be more specific, a wire embedded layer obtained from a wire embedded element) such that the interlayer connection via 50 extends in the thickness direction of the wire embedded element. As illustrated in the drawings, a step of forming the interlayer connection via 50 can be performed after step (ii) of the manufacturing method of this disclosure (and before step (iii), for example).

The interlayer connection via 50 can be obtained by forming a blind via after embedding the thick wire 20. In particular, after embedding the thick wire 20 (and after a wire embedded layer is obtained from the wire embedded element 11 by applying heat and/or light), a laser is applied from the second principal surface side (in other words, the principal surface B opposite the principal surface A in which the thick wire 20 is embedded) of the wire embedded layer to form a blind via (Refer to FIG. 13D). The blind via is filled with an electroconductive material to form an interlayer connection via (refer to FIG. 13E). The blind via may be filled with an electroconductive material by performing copper plating or using a conductive paste such as a Ag paste or a Cu paste. The size of the interlayer connection via 50 may be determined based on the required electrical resistance and wiring density. With a large via, the electrical resistance is low and a large current can be supplied but the number of vias that can be extracted per unit area is decreased. Forming small vias is difficult. For example, a via diameter may be 5 μm to 300 μm.

Formation of the blind via may be performed by photolithography. In such a case, the flexible film is preferably composed of a material that can be photopatterned. For example, a photosensitive epoxy sheet or a photosensitive PPE sheet may be used.

In this disclosure, the interlayer connection via and the thick wire are formed so as to be in a reverse taper relationship in which the direction a in which the width Wa of the interlayer connection via gradually decreases and the direction b in which the width Wb of the thick wire gradually decreases are opposite to each other (Refer to FIG. 13E). In other words, the interlayer connection via 50 preferably has a reverse tapered, conical frustum shape in which the cross sectional area on the principal surface side A is small. In such a flexible semiconductor device 100, the tapering effect of the thick wire and the tapering effect of the interlayer connection via can both be exhibited.

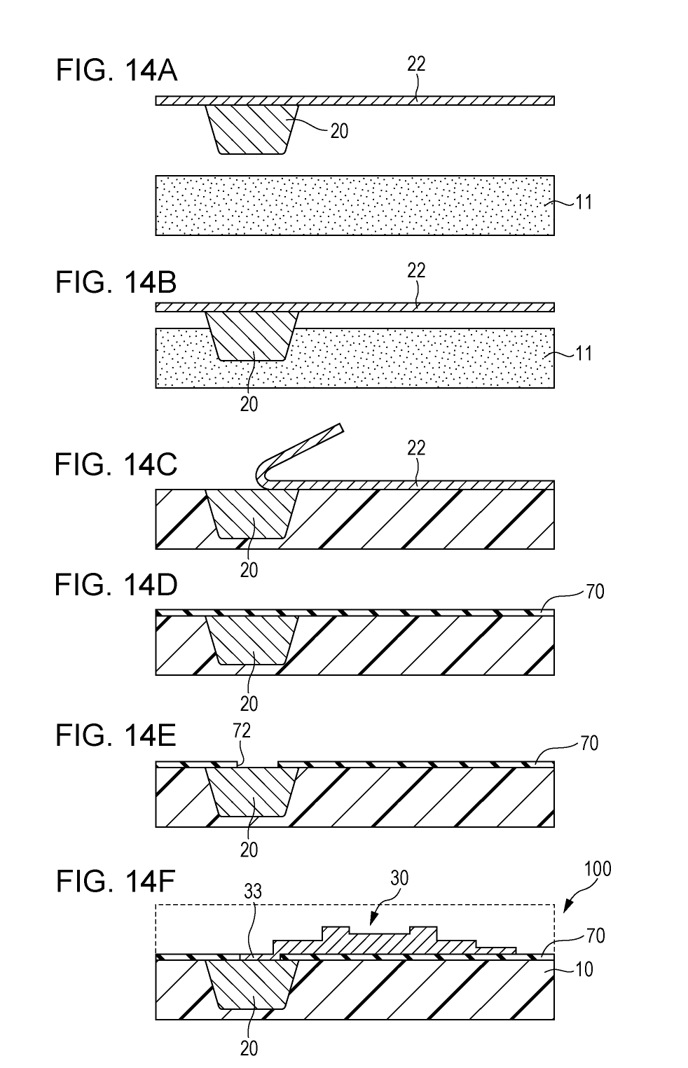

The manufacturing method of this disclosure may further include a step of forming a barrier. As illustrated in FIGS. 14A to 14F, the method may further include a step of forming a barrier layer 70 that directly covers the first principal surface of the wire embedded element (in particular, the wire embedded layer obtained from the wire embedded element) (refer to FIG. 14D in particular).

In order to exhibit a barrier function of blocking the passage of moisture, the barrier layer 70 may be formed as a multilayered film constituted by an inorganic film composed of SiO₂, SiN, or the like and a polymer film. For example, two or more pairs of SiO₂ (about 100 nm) and siloxane (about 100 nm) formed by CVD may be laminated and used. The barrier performance is improved by increasing the number of pairs to be laminated but this increases the cost for forming films. Accordingly, the number of pairs may be determined based on the desired barrier performance and the cost. For example, about 2 to 10 pairs of SiO₂ and siloxane may be laminated.

In forming the barrier layer 70, an opening 72 is preferably formed in the area above the thick wire 20 (refer to FIG. 14E) so that the thick wire 20 and the source electrode 33 of the TFT element can be connected to each other through the opening 72. The opening 72 may be formed by irradiating the barrier layer with a laser or by performing photolithography and etching.

The barrier layer can be used to further enhance planarity. For example, in the embodiment in which the thick wire slightly protrudes from the principal surface of the wire embedded layer, further planarization can be achieved by forming a barrier layer on the principal surface of the wire embedded layer so that the barrier layer is completely flush with the topmost surface of the protruding part.

The scope of the disclosure is not limited to the aforementioned preferred embodiments and various modifications and alterations are naturally possible as can be easily understood by persons skilled in the art.

For example, in the description above, the connection between the thick wire and the TFT element is established by the connection between the thick wire and the source electrode. However, the disclosure is not limited to this. Depending on the multilayered structure of the flexible semiconductor device, the thick wire and the drain electrode may be connected to each other. In other words, the drain electrode may be connected to the thick wire by being directly extracted from the thick wire.

A flexible semiconductor device of this disclosure includes the following: a wire embedded layer that has flexibility and has a first principal surface and a second principal surface; a thick wire embedded in the wire embedded layer (for example, a thick wire substantially flush with the first principal surface of the wire embedded layer); and a thin film transistor element electrically connected to the thick wire. The thin film transistor element is disposed on the first principal surface (the principal surface substantially flush with the thick wire) of the wire embedded layer.

One of the features of the flexible semiconductor device of this disclosure is that a thick wire is embedded in a wire embedded layer having flexibility. In other words, a thick wire thicker than wires typically used in the related art is embedded in a layer having flexibility. In particular, the thick wire embedded is substantially flush with the layer having flexibility.

The word “flexible” as used in the flexible semiconductor device in the description substantially means that the semiconductor device as a whole has flexibility that allows the semiconductor device to be bent. A flexible semiconductor device as defined in this disclosure can also be named “flexible semiconductor element” considering the structure of the device.

The disclosure also provides a display device that includes the flexible semiconductor device. In particular, a display device according to this disclosure includes a flexible semiconductor device and an image display unit including a plurality of pixels formed on the flexible semiconductor device. The flexible semiconductor device includes a wire embedded layer having flexibility and a thick wire embedded in the wire embedded layer so as to be substantially flush with a first principal surface of the wire embedded layer.

One of the features of this display device is that the flexible semiconductor device included therein has a wire embedded layer having flexibility and the wire embedded layer has a thick wire embedded therein so that the thick wire is substantially flush with a first principal surface of the wire embedded layer. In other words, in the display device of this disclosure, a wire thicker than that typically used in the related art is embedded in a layer having flexibility as in the flexible semiconductor device described above. In particular, the thick wire is embedded so as to be substantially flush with the layer having flexibility.

The disclosure also provides a method for manufacturing a flexible semiconductor device. A manufacturing method of this disclosure includes (i) a step of preparing a thick wire and a wire embedded element that has flexibility and has a principal surface; (ii) a step of embedding the thick wire in the wire embedded element by performing an operation of pressing the thick wire against the principal surface of the wire embedded element (for example, the thick wire is embedded in the wire embedded element so that the thick wire is substantially flush with the principal surface of the wire embedded element); and (iii) a step of forming a thin film transistor element on the principal surface (principal surface in which the thick wire is embedded to be flush with the principal surface) of the wire embedded element.

One of the features of this manufacturing method is that the method includes a process of embedding a thick wire in a wire embedded element having flexibility. In other words, in the manufacturing method of this disclosure, a step of embedding a wire thicker than those typically used in the related art in an element having flexibility is performed. In particular, the thick wire is embedded so as to be substantially flush with the element that has flexibility.

A flexible semiconductor device according to this disclosure can be used in various types of image display units (in other words, display devices). For example, the flexible semiconductor device can be used in an image display unit of a smart phone, an image display unit of a tablet terminal, an image display unit of a television, an image display unit of a cellular phone, an image display unit of a mobile computer or a laptop computer, an image display unit of a digital still camera or a camcorder, or an image display unit of an electronic paper. Moreover, the flexible semiconductor device can be applied to various prospective usages of printed electronics (for example, radiofrequency identifiers (RF-IDs), memories, micro processing units (MPUs), solar cells, and sensors).

What is claimed is:

1. A flexible semiconductor device comprising:
a wire embedded layer that has flexibility and has a first principal surface and a second principal surface;
a thick wire embedded in the wire embedded layer so as to be substantially flush with the first principal surface of the wire embedded layer; and
a thin film transistor element electrically connected to the thick wire,
wherein the thin film transistor element is disposed on the first principal surface of the wire embedded layer.

2. The flexible semiconductor device according to claim 1, wherein the thick wire is embedded in the wire embedded layer such that an upper surface of the thick wire protrudes from the first principal surface of the wire embedded layer.

3. The flexible semiconductor device according to claim 1, wherein the thick wire is embedded in the wire embedded layer such that an upper surface of the thick wire is recessed from the first principal surface of the wire embedded layer.

4. The flexible semiconductor device according to claim 1, wherein the thick wire has a tapered shape in which a width gradually decreases from the first principal surface toward the second principal surface of the wire embedded layer.

5. The flexible semiconductor device according to claim 1, wherein the thin film transistor element is disposed in an area outside an area above the thick wire.

6. The flexible semiconductor device according to claim 1, wherein the thick wire and the thin film transistor element are electrically connected to each other through a connection between the thick wire and a source electrode of the thin film transistor element, and
the source electrode is positioned in at least part of an upper surface of the thick wire.

7. The flexible semiconductor device according to claim 1, wherein the wire embedded layer includes a flexible film and an adhesive layer disposed on the flexible film, and
the thick wire is embedded in the adhesive layer.

8. The flexible semiconductor device according to claim 1, wherein an interlayer connection via extending in a thickness direction of the wire embedded layer is formed in the wire embedded layer.

9. The flexible semiconductor device according to claim 8, wherein the interlayer connection via has a tapered shape in which a width gradually increases from the first principal surface toward the second principal surface of the wire embedded layer.

10. The flexible semiconductor device according to claim 9, wherein the thick wire has a tapered shape in which a width gradually decreases from the first principal surface toward the second principal surface of the wire embedded layer, and
the interlayer connection via and the thick wire are in a reverse taper relationship where the direction in which the width of the interlayer connection via gradually decreases and the direction in which the width of the thick wire gradually decreases are opposite to each other.

11. The flexible semiconductor device according to claim 1, wherein the thick wire is formed of a metal foil.

12. The flexible semiconductor device according to claim 1, wherein the thick wire and the thin film transistor element are electrically connected to each other through a connection between the thick wire and a source electrode of the thin film transistor element,
the source electrode is positioned in at least part of an upper surface of the thick wire,
the flexible semiconductor device further comprises a barrier layer directly covering the first principal surface of the wire embedded layer,
an opening is formed in the barrier layer in a local area above the thick wire, and
the thick wire and the source electrode are connected to each other through the opening.

13. A display device comprising:
the flexible semiconductor device according to claim 1; and
an image display unit including a plurality of pixels formed on the flexible semiconductor device.

14. The display device according to claim 13, wherein the image display unit comprises
a pixel electrode formed on the flexible semiconductor device;
an emitting layer formed on the pixel electrode; and
a transparent electrode layer formed on the emitting layer.

15. A method for manufacturing a flexible semiconductor device, the method comprising:
(i) a step of preparing a thick wire and a wire embedded element that has flexibility and has a principal surface;
(ii) a step of embedding the thick wire in the wire embedded element by performing an operation of pressing the thick wire against the principal surface of the wire embedded element so that the thick wire is substantially flush with the principal surface of the wire embedded element; and
(iii) a step of forming a thin film transistor element on the principal surface of the wire embedded element.

16. The method according to claim 15, wherein, in step (ii), the thick wire is embedded in the wire embedded element such that an upper surface of the thick wire is positioned to be higher than the principal surface of the wire embedded element.

17. The method according to claim 15, wherein, in step (ii), the thick wire is embedded in the wire embedded element such that an upper surface of the thick wire is positioned to be lower than the principal surface of the wire embedded element.

18. The method according to claim 15, wherein, in step (i), the thick wire is formed by processing a metal foil.

19. The method according to claim 15, wherein, in step (i), the thick wire is prepared as a carrier-mounted thick wire in which the thick wire is mounted on a carrier.

20. The method according to claim 15, wherein, in step (i), the wire embedded element is prepared to have a double layer structure constituted by a flexible film and an adhesive layer disposed on the flexible film.

21. The method according to claim 15, wherein, in step (i), the thick wire is prepared to have a tapered shape in which a width gradually decreases; and
in step (ii), a surface of the thick wire, the surface having a relatively small width, is pressed against the principal surface of the wiring embedded element so as to have the thick wire embedded in the wire embedded element.

22. The method according to claim 15, further comprising a step of forming an interlayer connection via extending in a thickness direction of the wire embedded element.

23. The method according to claim 22, wherein, in step (i), the thick wire is prepared to have a tapered shape in which a width gradually decreases,
in step (ii), a surface of the thick wire, the surface having a relatively small width, is pressed against the principal surface of the wiring embedded element so as to have the thick wire embedded in the wire embedded element, and
the step interlayer connection via is formed to be in a reverse taper relationship with the thick wire, where a direction in which a width Wa of the interlayer connection via gradually decreases and a direction in which a width Wb of the thick wire gradually decreases are opposite to each other.

24. The method according to claim 15, wherein, in step (iii), the thin film transistor element is formed in an area outside an area above the thick wire.

25. The method according to claim 15, further comprising a step of forming a barrier layer that directly covers the principal surface of the wire embedded element,
wherein an opening is formed in the barrier layer in a local area above the thick wire and the thick wire and a source electrode of the thin film transistor element are connected to each other through the opening.
